(19) United States
(12) Patent Application Publication
(10) Pub. No.: US 2011/0120651 A1
(43) Pub. Date: May 26, 2011

(54) SHOWERHEAD ASSEMBLY WITH IMPROVED IMPACT PROTECTION

(75) Inventors: ALEX ERENSTEIN, San Jose, CA (US); MICHAEL D. WILLWERTH, Campbell, CA (US); DAVID PALAGASHVILI, Mountain View, CA (US)

(73) Assignee: APPLIED MATERIALS, INC., Santa Clara, CA (US)

(21) Appl. No.: 12/892,036

(22) Filed: Sep. 28, 2010

Related U.S. Application Data
(60) Provisional application No. 61/261,987, filed on Nov. 17, 2009.

(51) Int. Cl. B05B 1/00; C23F 1/08; C23C 16/455

(52) U.S. Cl. 156/345.34; 239/288.5; 118/728

(57) ABSTRACT

Showerhead assemblies with improved impact protection are provided herein. In some embodiments, a showerhead assembly includes a body having a plenum disposed therein, the body having a plurality of first holes extending from the plenum to a substrate facing surface of the body; a plate disposed on the substrate facing surface of the body and having a plurality of second holes formed therethrough, each second hole corresponding with a respective first hole of the body; and a lip extending from the body and circumscribing the plate, the lip extending beyond a chamber facing surface of the plate. In some embodiments, the showerhead assembly is disposed in the inner volume of a process chamber.

### CROSS-REFERENCE TO RELATED APPLICATIONS

This application claims benefit of U.S. provisional patent application Ser. No. 61/261,987, filed Nov. 17, 2009, which is herein incorporated by reference.

### FIELD

Embodiments of the present invention generally relate to substrate processing equipment, and more specifically to showerhead assemblies for use in such processing equipment.

### BACKGROUND

Some substrate processing equipment may include components, such as a showerhead assembly, for distributing a process gas into a process chamber. For example, the showerhead assembly may distribute the process gas to a substrate surface. The showerhead assembly can include a protective plate, which can be utilized to protect the holes or the body of the showerhead from damage. Such damage may occur, for example, from exposure to a plasma formed in the processing equipment, or by removing the showerhead from the processing equipment such as for maintenance or cleaning.

However, the protective plate is made of a delicate material, such as ceramic, and the inventors have discovered that the protective plate can be damaged, such as chipped, during removal and handling of the showerhead assembly. If unchecked, a damaged protective plate may provide a source of contamination to a substrate during processing in the processing equipment.

Accordingly, the inventors have provided an improved showerhead assembly to minimize damage to the protective plate.

### SUMMARY

Showerhead assemblies with improved impact protection are provided herein. In some embodiments, a showerhead assembly includes a body having a plenum disposed therein, the body having a plurality of first holes extending from the plenum to a substrate facing surface of the body; a plate disposed on the substrate facing surface of the body and having a plurality of second holes formed therethrough, each second hole corresponding with a respective first hole of the body; and a lip extending from the body and circumscribing the plate, the lip extending beyond a chamber facing surface of the plate. In some embodiments, the showerhead assembly is disposed in the inner volume of a process chamber. Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a showerhead assembly in accordance with some embodiments of the present invention.

FIG. 2 depicts a schematic side view of a processing apparatus in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of a showerhead assembly and apparatus using same are provided herein. The inventive showerhead assembly advantageously limits or prevents damage to a protective layer disposed on a substrate facing side of the showerhead body.

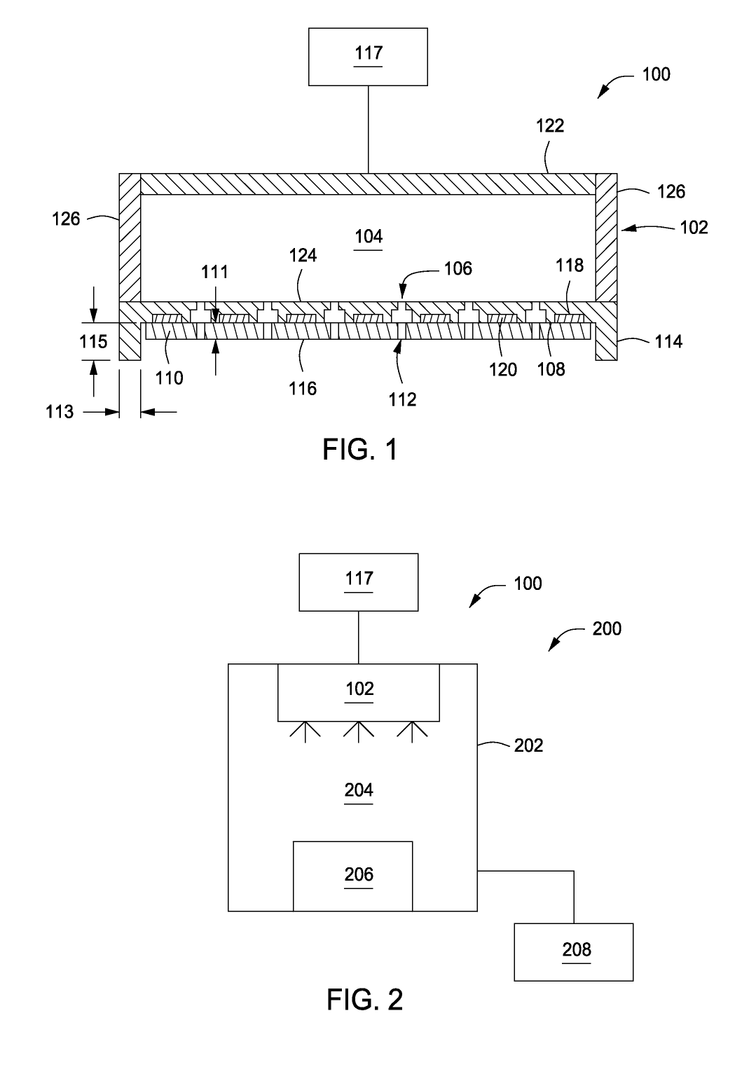

FIG. 1 depicts a schematic side view of a showerhead assembly in accordance with some embodiments of the present invention. The showerhead assembly 100 includes a body 102 having a plenum 104 disposed therein. The body 102 includes a plurality of first holes 106 extending from the plenum 104 to a substrate facing surface 108 of the body 102. The substrate facing surface 108 may be called such because the surface 108 may face a substrate being processed in an apparatus including the showerhead assembly 100.

The body 102 may be formed of a one-piece construction, or alternatively, may be constructed from several components. For example, the body 102 may be formed by providing a top plate 122 and a bottom plate 124 and having an annular or other appropriate shaped body 126 coupled together to form the body 102 and define the plenum 104 therebetween. In some embodiments, the body 102 may be formed of dielectric materials. In some embodiments, the body 102 may comprise a conducting material, for example, if the showerhead assembly includes an electrode for providing RF power to form a plasma. In some embodiments, the body 102 comprises at least one of aluminum (Al), stainless steel, or titanium (Ti). In some embodiments, the body 102 is aluminum (Al).

The plurality of first holes 106 extend from the plenum 104 to the substrate facing surface 108 of the body 102. The plurality of first holes 106 may be provided in any suitable arrangement for flowing a process gas from the plenum 104 into a process chamber. For example, the plurality of first holes 106 may be arranged in a symmetric pattern, a repeating pattern, random, or any other suitable geometry. The first holes 106 may have any suitable diameter and may be uniform in diameter or may vary in diameter (as shown).

In some embodiments, the plurality of first holes 106 may be arranged in zones, for example, having a first zone proximate a center of the body (for example corresponding to a center of a substrate when positioned under the showerhead), a second zone proximate an outer edge of the body. In some embodiments, additional zones may be provided as well. The pattern, number, and/or size of the holes in each zone may be independently provided as desired to facilitate a desired gas flow pattern. Although not shown, the plenum 104 may also be split into one or more zones. In some embodiments, the zones of the plenum 104 may correspond directly to the zones of the first holes 106. In some embodiments, one or more of the zones of the plenum 104 may have a plurality of zones of first holes 106 distributed therein.

Each first hole 106 may be oriented in any suitable direction necessary to deliver a process gas from the plenum 104. For example, each first hole 106 may be oriented perpendicular to the substrate facing surface 108 as shown, at angle to the substrate facing surface 108, or a combination thereof. Each first hole 106 may be formed having a uniform diameter therethrough as shown. Alternatively or in combination, one or more of the first holes 106 may have a non-uniform diameter, for example, having a larger diameter at the substrate facing surface 108 of the body 102. For example, non-uniform diameter may include a diameter which varies linearly or non-linearly, or may include multiple diameters. For example, a first hole may include a first portion having a first diameter and a second portion having a second diameter (not shown).

In some embodiments, the assembly 100 further includes a plate 110 disposed on the substrate facing surface 108 of the body. The plate 110 may have a plurality of second holes 112 formed therethrough corresponding with respective first holes 106 of the body 102. The plate 110 may be utilized to protect the body 102, for example, from damage by a plasma formed from a process gas, or may be utilized as a heat sink during processing or the like. The plate 110 may be formed of a first material. The first material may be a ceramic or dielectric material, for example, such as one or more of yttrium oxide (Y₂O₃), or an advanced ceramic material (e.g., ceramic materials used in specialized, recently developed applications). In some embodiments, the plate 110 is formed of yttrium oxide (Y₂O₃). In some embodiments, the plate 110 may comprise a second material coated with the first material.

Each second hole 112 may be substantially similar to each first hole 106 as discussed above, and for example, may be perpendicular or at an angle to the chamber facing surface 116 of the plate 110 to either match the orientation of a corresponding first hole 106, or may be oriented differently from a corresponding first hole 106 to change the flow direction of a process gas flowing therethrough. Each second hole 112 may have a uniform or non-uniform diameter as discussed above for the first holes 106. Each second hole 112 may be of the same, greater, or lesser diameter (illustrated in FIG. 1) as a corresponding first hole 106. A gas source 117 may be coupled to the body 102 to provide one or more process gases to the plenum 104 during use. The one or more process gases may be distributed from the plenum 104 into a process chamber via the first and second holes.

The plate 110 may be fastened to the substrate facing surface 108 in any suitable manner, such as clamps, fasteners, gluing, bonding, or the like. In some embodiments, a bond layer 120 may be disposed between the substrate facing surface 108 and the plate 110. The bond layer 120 eliminates use of bolts for securing the plate 110 to the body 102 and consequently reduces mechanical stresses on the showerhead assembly 100. The bond layer 120 may be ductile and compliant to provide an interface that absorbs the stresses arising from the thermal expansion mismatch between the plate 110 and the body 102. The bond layer 120 may have a thickness between about 0.001 to about 0.040 inches. The bond layer 120 may comprise at least one of a polymer or epoxy.

In some embodiments (as illustrated in FIG. 1), the body 102 further comprises a plurality of recesses 118 disposed in the substrate facing surface 108 of the body 110. Each recess may be disposed between a pair of first holes 106, and/or between a first hole 106 and a peripheral edge of the substrate facing surface 108. As illustrated in FIG. 1, the bond layer 120 may comprise a plurality of bonding segments, where each segment is disposed in a corresponding recess. Each bonding segment may have a thickness between about 0.001 to about 0.040 inches. In some embodiments, the thickness of each segment is about 0.010 inches. The inventors have discovered that by recessing the bond layer as illustrated in FIG. 1, the bond layer may be made thicker than in a non-recessed bond layer. The inventors have further found that the added thickness of the bond layer reduces stress due to thermal expansion mismatch between the materials comprising the body 102 (e.g., aluminum) and the materials comprising the plate 110 (e.g., yttrium oxide).

A lip 114 extends from the body 102 and circumscribes the plate 110 to form a recess in which the plate is disposed. The lip 114 extends beyond a chamber facing surface 116 of the plate 110. The lip 114 may be a contiguous piece of the body 102, as shown. Alternatively, the lip 114 may be one or more separate pieces attached to the body 102 by a fastener, weld, or the like (not shown). The lip 114 protects the chamber facing surface 116 of the plate 110 from damage, such as when the showerhead assembly 100 is removed from a process chamber for servicing, or cleaning, or alternatively, during installation of the showerhead assembly 100 into a process chamber. The lip 114 may further protect the plate 110 from damage if the showerhead is placed on a hard surface having debris or an uneven surface that could otherwise damage or crack the plate 110. In some embodiments, the lip 114 may have a thickness 115 that is between about 0.010 to about 0.050 inches greater than a thickness 111 of the plate. In some embodiments, the thickness 115 of the lip 114 is about 0.020 inches greater than the thickness 111 of the plate 110.

The lip 114 may further protect the plate 110 from damage due to side impact along the peripheral edge of the plate 110. The lip 114 may have a width 113 suitable to prevent damage or breakage of the lip 114 due to contact with another component or surface. In some embodiments, the width 113 may be between about 0.02 to 0.30 inches. In some embodiments, the width 113 of the lip 114 is about 0.10 inches.

The showerhead assembly 100 may be included in a processing apparatus, such as the processing apparatus 200 depicted in FIG. 2. The processing apparatus 200 includes a process chamber 202 having an inner volume 204. The processing apparatus 200 may be utilized alone or, as a processing module of an integrated semiconductor substrate processing system, or cluster tool, such as a CENTURA® integrated semiconductor wafer processing system, available from Applied Materials, Inc. of Santa Clara, Calif. Examples of suitable processing apparatus that may advantageously benefit from modification in accordance with embodiments of the present invention include processing apparatus such as capacitively coupled plasma reactors such as any of the PRODUCER® line of processing equipment, also available from Applied Materials, Inc. The above listing of semiconductor equipment is illustrative only, and other etch reactors, and non-etch equipment (such as CVD reactors, or other semiconductor processing equipment) may also be suitably modified in accordance with the present teachings.

The process chamber 202 further includes a substrate support 206 for retaining a substrate thereon. The showerhead assembly 100 may generally be disposed above the substrate support 206. As discussed above, the showerhead assembly 100 may further include an electrode (not shown) for forming a plasma from one or more process gases entering the inner volume 204 of the process chamber 202 via the showerhead assembly 100. The plasma may be utilized, for example, to etch a substrate retained on the substrate support 206. Accordingly, the processing apparatus may further include components, such as a plasma source coupled to the electrode via a match network or the like (not shown).

The process apparatus 200 further includes a controller 208 coupled to the process chamber 202 and/or to one or more of the various chamber components for controlling the operation thereof. The controller 208 comprises a central processing unit (CPU), a memory, and support circuits for the CPU and facilitates control of the components of the apparatus 200 and, as such, of methods of forming a plasma, or other methods utilized in a process chamber having the inventive showerhead, such as methods of etching a substrate or the like. The controller may be one of any form of general-purpose computer processor that can be used in an industrial setting for controlling various chambers and sub-processors. The memory, or computer-readable medium of the CPU may be one or more of readily available memory. Processing methods may be stored in the memory as a software routine that may be executed or invoked to control the operation of the apparatus in the manner described above.

Thus, embodiments of an improved showerhead assembly and an apparatus using the same are provided herein. The inventive showerhead assembly advantageously limits damage to a protective layer disposed on a substrate facing surface of the showerhead body.

While the foregoing is directed to embodiments of the present invention, other and further embodiments of the invention may be devised without departing from the basic scope thereof.

1. A showerhead assembly, comprising:
a body having a plenum disposed therein, the body having a plurality of first holes extending from the plenum to a substrate facing surface of the body;
a plate disposed on the substrate facing surface of the body and having a plurality of second holes formed therethrough, each second hole corresponding with a respective first hole of the body; and
a lip extending from the body and circumscribing the plate, the lip extending beyond a chamber facing surface of the plate.

2. The showerhead assembly of claim 1, wherein the thickness of the lip is between about 0.010 to about 0.050 inches greater than the thickness of the plate.

3. The showerhead assembly of claim 1, further comprising:
a bond layer disposed between the body and the plate to couple the plate to the body.

4. The showerhead assembly of claim 3, wherein the bond layer has a thickness between about 0.001 to about 0.040 inches.

5. The showerhead assembly of claim 3, wherein the bond layer comprises at least one of a polymer or an epoxy.

6. The showerhead assembly of claim 3, wherein the body further comprises:
a plurality of recesses disposed in the substrate facing surface of the body, each recess disposed between a pair of first holes.

7. The showerhead assembly of claim 6, wherein the bond layer further comprises:
a plurality of bonding segments, each segment disposed in each recess.

8. The showerhead assembly of claim 7, wherein each bonding segment has a thickness between about 0.001 to about 0.040 inches.

9. The showerhead assembly of claim 1, wherein the plate comprises yttrium oxide (Y₂O₃).

10. The showerhead assembly of claim 1, wherein the plate comprises an advanced ceramic material.

11. The showerhead assembly of claim 1, wherein the body comprises at least one of aluminum (Al), stainless steel, or titanium (Ti).

12. The showerhead assembly of claim 1, wherein the lip has a width between about 0.02 to about 0.30 inches.

13. The showerhead assembly of claim 1, wherein the body comprises a top plate and a bottom plate coupled to an annular body to define the plenum therebetween, wherein the lip extends from the bottom plate.

14. An apparatus, comprising:
a process chamber having an inner volume;
a substrate support for retaining a substrate thereon disposed in the inner volume of the process chamber; and
a showerhead assembly disposed above the substrate support and within the inner volume of the process chamber, the showerhead assembly further comprising:
a body having a plenum disposed therein, the body having a plurality of first holes extending from the plenum to a substrate facing surface of the body;
a plate disposed on the substrate facing surface of the body and having a plurality of second holes formed therethrough, each second hole corresponding with a respective first hole of the body; and
a lip extending from the body and circumscribing the plate, the lip extending beyond a chamber facing surface of the plate.

15. The apparatus of claim 14, wherein the thickness of the lip is between about 0.010 to about 0.050 inches greater than the thickness of the plate.

16. The apparatus of claim 14, wherein the lip has a width between about 0.02 to about 0.30 inches.

17. The apparatus of claim 14, wherein the plate comprises yttrium oxide (Y₂O₃).

18. The apparatus of claim 14, wherein the plate comprises an advanced ceramic material.
